(19) United States
(12) Patent Application Publication
(10) Pub. No.: US 2016/0233502 A1
(43) Pub. Date: Aug. 11, 2016

(54) Lithium ion Battery Cell With Single Crystal Li+- Intercalated Titanium Dioxide As An Anode Material

(71) Applicant: Nokomis, INC., Charleroi, PA (US)

(72) Inventors: Adam Taylor Brant, Bethel Park, PA (US); Walter John Keller, Bridgeville, PA (US)

(73) Assignee: Nokomis, INC., Charleroi, PA (US)

(21) Appl. No.: 14/495,963

(22) Filed: Sep. 25, 2014

Related U.S. Application Data
(60) Provisional application No. 61/966,654, filed on Feb. 27, 2014.

(51) Int. Cl. H01M 4/485; H01M 10/0525; H01M 10/0568; C30B 31/02; H01M 10/658; H01M 10/625; C30B 29/32; H01M 4/525; H01M 2/12

(52) U.S. Cl. CPC H01M 4/485; H01M 4/525; H01M 10/0525; H01M 10/0568; H01M 2/1264; H01M 10/658; H01M 10/625; C30B 29/32; C30B 31/02; H01M 2004/027

(57) ABSTRACT

A nonaqueous battery cell includes a casing, a negative electrode provided in the casing, the negative electrode including lithium ions intercalated into a single crystal of a titanium dioxide (TiO₂), in the rutile phase, with concentration on the order of 10¹⁶ cm⁻³, a positive electrode provided in the casing, a separator separating the negative electrode from the positive electrode, and an electrolyte disposed in the casing.

A method of manufacturing a negative electrode material to be used in a nonaqueous battery cell includes the steps of burying a titanium dioxide (TiO₂) into a lithium hydroxide powder, heating, in a furnace, the titanium dioxide buried in the lithium hydroxide powder at about 450° Celsius for 6 or more hours, and isolating a single lithium ion within a C-axis channels aligned along the crystallographic direction of the single TiO₂ crystal.

### CROSS-REFERENCE TO RELATED APPLICATIONS

This application is related to and claims under 35 U.S.C. §119(e) priority from and benefit of U.S. Provisional Patent Application Ser. No. 61/966,654 filed on Feb. 27, 2014 and titled “Lithium ion Battery Cell With Single Crystal Li⁺-Intercalated Titanium Dioxide (TiO₂) As An Anode Material”.

### STATEMENT REGARDING FEDERALLY SPONSORED RESEARCH AND DEVELOPMENT

N/A

### REFERENCE TO SEQUENCE LISTING, A TABLE, OR A COMPUTER PROGRAM LISTING COMPACT DISC APPENDIX

N/A

### BACKGROUND

1. Technical Field

The subject matter relates, in general, to lithium-ion (Li-ion) batteries. The subject matter further relates to a lithium-ion battery cell or a series of lithium-ion battery cells, each employing a single-crystalline Li⁺-intercalated titanium dioxide (TiO₂) crystal, in a rutile phase, as an anode (a negative electrode during discharge) material.

2. Description of Related Art

Lithium-ion batteries offer significant advantages in military and aerospace applications, as they are light weight and possess a higher cell-life and a greater energy density than their nickel-cadmium and lead-acid counterparts.

Lithium-ion batteries are particularly attractive for use on a military aircraft due to their high energy density coupled with light weight and small physical dimension. Despite these advantages, major safety issues exist, as evidenced by several fires related to Li-ion batteries that have occurred on military and commercial aircraft, including aboard the Boeing 787. These multi-cell batteries can suffer from internal electrical shorts, overcharging/overdischarging, and overheating, resulting in catastrophic fires. These issues are exacerbated when thermal runaway or cell-to-cell propagation of an individual cell failure occurs, whereby the heat is transferred from an overheating cell to its neighboring cells, causing overheating and subsequent breakdown of neighboring cells.

Aviation Week and Space Technology has identified thermal runaway as a “main risk”. Thermal runaway is a situation in which an increase in temperature changes environmental conditions in such a way that a further temperature increase occurs. Thermal runaway describes a process by which energy is released more rapidly as a result of increased temperature. This release of energy further increases temperature, and a cyclical reaction ensues. Thus, thermal runaway can have critical consequences, and the advantages offered by lithium-ion batteries are of little practical use if the issue of thermal runaway is not addressed.

Therefore, there is a need for a lithium-ion battery cell or battery containing a series of lithium-ion battery cells that is characterized by a high energy density, improved thermal safety, reduced materials cost, and reduced manufacturing costs.

### BRIEF DESCRIPTION OF THE FIGURES

FIG. 1 illustrates an example of a schematic view of a rechargeable lithium-ion battery cell;

FIG. 2 illustrates an example of a 3-D schematic view of a titanium dioxide (TiO₂) rutile lattice with intercalated Li⁺ ions;

FIG. 3 illustrates an example of a planar view of the titanium dioxide (TiO₂) rutile of FIG. 2 in a plane normal to the [001] crystallographic direction;

FIG. 4 illustrates an example of an Electron Paramagnetic Resonance (EPR) spectrum of a single Li⁺ ion in TiO₂ rutile, particularly observed only after diffusing Li⁺ ions into the crystal lattice; and

FIG. 5 illustrates an example of a schematic view of a rechargeable multi-cell lithium-ion battery cell.

### DETAILED DESCRIPTION

Prior to proceeding to the more detailed description of the present invention, it should be noted that, for the sake of clarity and understanding, identical components which have identical functions have been identified with identical reference numerals throughout the several views illustrated in the drawing figures.

The following detailed description is merely exemplary in nature and is not intended to limit the described examples or the application and uses of the described examples. As used herein, the words “example”, “exemplary” or “illustrative” means “serving as an example, instance, or illustration.” Any implementation described herein as “example”, “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims.

The subject matter relates to lithium-ion battery cell using material that has a single crystal Li⁺-intercalated titanium dioxide (TiO₂) in the rutile phase or form. The subject matter may relate to a rechargeable non-aqueous lithium-ion battery cell or a series of lithium-ion battery cells, each employing a material having a single-crystalline Li⁺-intercalated titanium dioxide (TiO₂) crystal, in a rutile phase or form. This material may be used as an anode (a negative electrode during discharge) or a cathode (a positive electrode during discharge). Li⁺ ions may be diffused into TiO₂ at a temperature of at least 425° Celsius for a time duration of six hours or more.

The lithium-ion battery cell with Li⁺-intercalated TiO₂ as the anode electrode material, may have a reduced thermal breakdown, as compared to conventional batteries. The series of lithium-ion battery cells may have a reduced thermal propagation of cell failure due to both a reduction of thermal runaway and a mitigation of heat transfer from cell to cell.

Use of TiO₂ as the anode material may greatly improve safety of the lithium-ion battery presently in use, as this material exhibits a higher lithiation potential than graphite and therefore low occurrences of lithium electroplating, which causes short circuiting within the anode. The material may be manufactured by intercalating large concentrations of Li⁺ ions into the TiO₂ crystal lattice.

The subject matter may allow for a reduced thermal breakdown, and thermal propagation of cell failure may be reduced by both a reduction of thermal runaway and a mitigation of heat transfer from cell to cell. Furthermore, the subject matter may greatly improve the safety of the lithium-ion battery, as this material exhibits a higher lithiation potential than graphite and low occurrences of lithium electroplating, which causes short circuiting. Additionally, the subject matter may drastically reduce cell failure and cell-to-cell propagation of cell failure in a lithium battery.

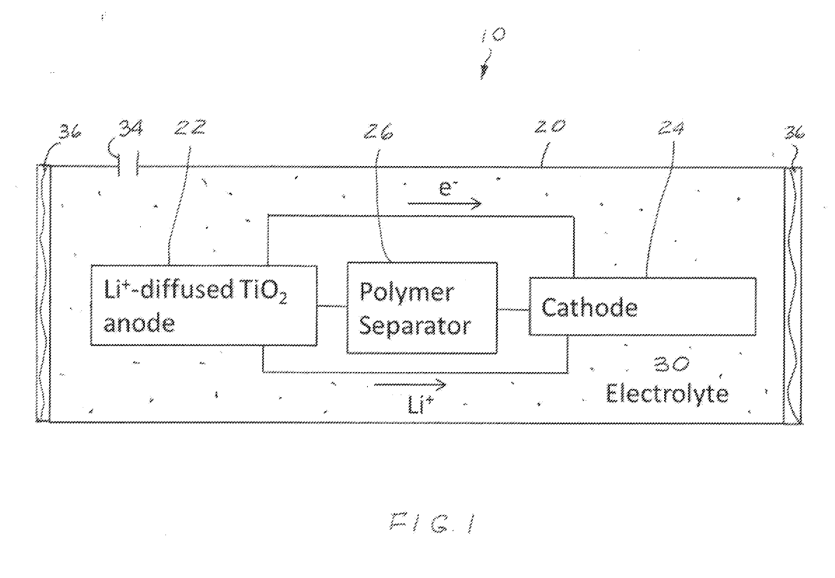

Now in reference to FIG. 1, a rechargeable nonaqueous electrochemical lithium-ion battery cell, generally designated as 10, comprises an anode or a negative electrode, during discharge, 22, a cathode or a positive electrode, during discharge, 24, a polymer separator 26 separating the anode 22 and the cathode 24, all being surrounded by an electrolyte solution or electrolyte 30 and encased by a casing member 20. The electrolyte 30 may include a lithium salt and an organic solvent.

The anode 22 may include various crystalline phases, including at least one of a single crystalline anatase, rutile, brookite, and amorphous titanium dioxide (TiO₂). The anode 22 may contain a material being manufactured by intercalating Li⁺ ions into only a TiO₂ (rutile) crystal. The cathode 24 contains material being preferably manufactured from a lithium cobalt oxide (LiCoO₂).

Table 1 demonstrates a comparison of specific capacity, specific energy, and energy density between TiO₂ and two materials commonly used as anode materials for Li-ion batteries. The graphite material may be characterized by a high lithium electroplating potential and potential occurrence of short circuiting within the material. Li₄Ti₅O₁₂ may be characterized by a low capacity (low energy density).

TABLE 1

| | Specific | Specific | Energy |
|---|---|---|---|
| | Capacity | energy at 3 V | Density at 3 V |
| Material | (Ma · h/g) | (W · h/kg) | (W · h/l) |
| Graphite | 372 | 1116 | 830 |
| Li₄Ti₅O₁₂ | 175 | 525 | 613 |
| TiO₂ (rutile) | 335 | 1008 | 1421 |

The theoretical specific capacity of TiO₂, is calculated using Faraday's law, equation (1):

m=QM/FZ (1)

where m is the mass of substance liberated at the electrode, Q is the total charge, F is Faraday's constant, M is the molar mass of the substance, and Z is the valence. The maximum theoretical specific capacity is approximately 335 mA·hr/g. The specific energy of the TiO₂ (rutile) at 3 V is then approximately 1000 W·hr/kg. TiO₂ (rutile) also offers high capacity for Li⁺ ions and higher structural stability, as demonstrated by its less than 4% change in lattice volume after lithium intercalation. This material has an extremely high diffusion constant along the [001] crystallographic direction, and excellent structural stability.

TiO₂ may be advantageous over graphite, the commonly used anode material, in terms of its thermal properties, particularly its lower potential for thermal failure due to reduced Li electroplating and short circuiting, a common problem with graphite based anode materials. Lithium electroplating occurs when the transport rate of Li⁺ ions to the anode exceeds the rate that Li⁺ can be inserted into the anode material, resulting in Li⁺ ions being deposited as metallic Li. Deposition of metallic Li into the anode causes short circuiting within the anode material, leading to accelerated degradation and catastrophic battery failure. The lithiation potential of this material is approximately 1.5-1.8 V vs. Li/Li⁺ as compared to 0.1 V vs. Li/Li⁺ in graphite. This higher lithiation potential may result in greatly reduced lithium electroplating, and hence reduces thermal runaway associated with this phenomenon. Reduction of thermal runaway at the cell-level is the first step toward improving the thermal safety and usefulness of the battery.

An extent of degradation of the battery cell 10 may be tested for a decline in capacity, or capacity fade. Capacity fade is a technique that describes the extent to which the charge capacity of the battery cell 10 has diminished over time. The capacity of the battery cell 10 is defined by the equation (2) as:

Cap(A·hr)=∫Idt (2)

where I is the discharge current and t is discharge time, in hours.

Capacity measurements may be performed by measuring the voltage as a function of time across a resistor that is in series with the cell, and calculating the current as a function of time using Ohm's Law. The current is then used to calculate capacity using the above equation 2.

As was stated above, the maximum theoretical capacity of TiO₂ is 335 mA·hr/g. The practically operable maximum capacity of the battery cell 10 may be at 60-70% of the theoretical capacity of TiO₂. These levels may be contemplated due to the fact that the actual capacity of batteries is always lower than their maximum theoretical capacity. As the battery cell 10 undergoes thermal stress, the capacity decreases. The decrease in capacity characterizes aged batteries, and may be a good indicator of decline in performance.

Physical dimensions of the single battery cell 10 may be approximately 5×20×20 mm and the weight of the single battery cell 10 may be less than 220 grams. The battery cell 10 may further comprise an insulating thermal foil 36 that encloses the casing 20 and that conforms to the size and shape of the casing 20 so as to mitigate a propagation of thermal breakdown external to the casing 20. The type and thickness of the foil 36 can be determined by various means, for example by the results of a thermal breakdown test. Thus, the nonaqueous battery cell 10 further comprises a layer or layers of material that diffuses hot spots (thermally conductive material) and material that mitigates heat transfer to neighboring cells (thermally insulating material) disposed on and surrounding an exterior surface of the casing 20 to distribute the heat evenly throughout and to conduct the heat to the outside of the case to reduce heat concentration in any one location.

Reduced thermal breakdown may be quantified by comparing the lithiation potential of TiO₂ with other common anode materials in Table 2. A paper by A. G. Dylla, et al. entitled “Lithium Insertion in Nanostructured TiO₂(B) Architectures” (Accounts of Chemical Research 46 1104 (2013)) states that a higher lithiation potential reduces the chance of thermal battery failure. The paper states “The fact that graphite lithiates at a potential near that of the Li/Li⁺ couple poses a problem in that the lithium electroplating can cause short circuit and thermal runaway conditions resulting in combustion of organic electrolyte and catastrophic battery failure. Choosing an anode with a higher lithiation potential such as TiO₂ (˜1.6 V vs Li/Li⁺) greatly reduces the chance of this type of battery failure.”

TABLE 2

| Material | Lithiation potential |
|---|---|
| Graphene | 0.1 |
| Lithium titanium oxide | 1.5 |
| TiO₂ | 1.6 |

There is also disclosed a method for manufacturing a negative electrode material to be used in a battery and effectively diffusing Li⁺ ions into TiO₂ rutile crystals. The method may comprise the steps of burying the TiO₂ rutile material in a lithium hydroxide (LiOH) powder, and heating the mixture, resulting in concentrations of lithium ions in the electrode material on the order of between 5×10¹⁵-1×10¹⁷ cm⁻³ and, may be resulting in a concentration of lithium ions on the order of about 10¹⁶ cm⁻³ are diffused into the material. After the diffusion process is complete, the crystal is cooled, for example, under ambient conditions.

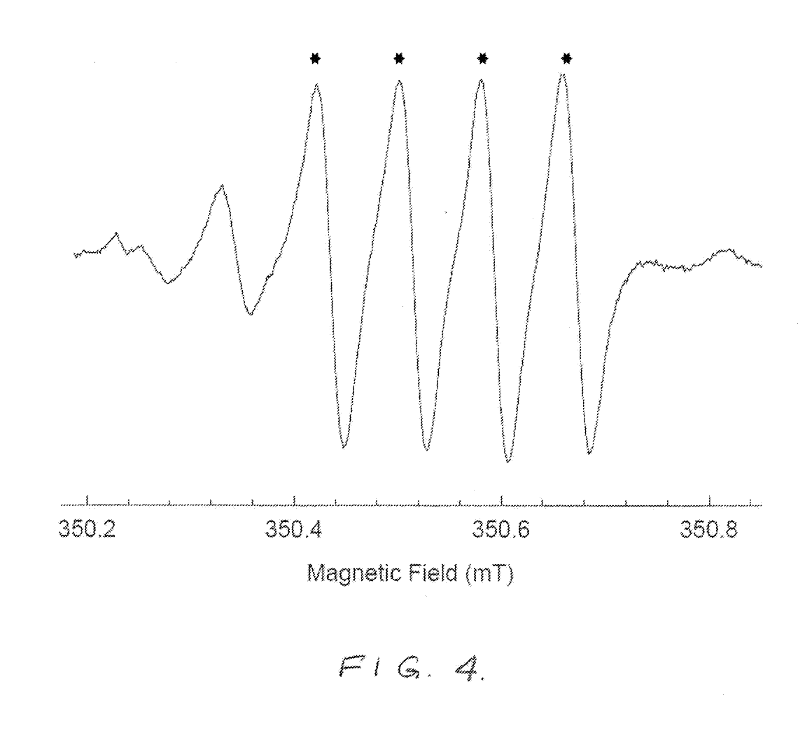

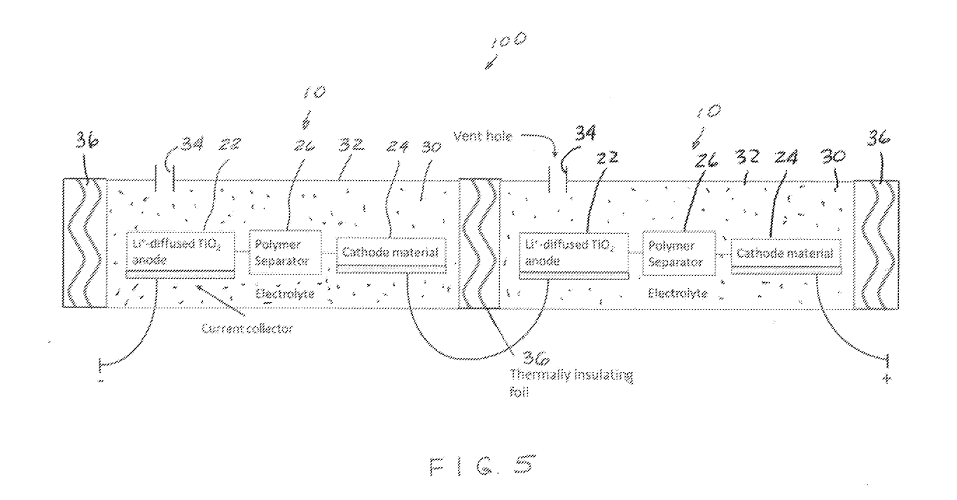

This concentration may be similar to a concentration that would result from intentionally doping the crystal during the growth process. This concentration may be also higher than the concentration of a trace lithium impurity, an impurity that unintentionally gets into the crystal during growth. This concentration of lithium ions may be also below the sensitivity of many analysis techniques, such as Raman spectroscopy and NMR. Analysis techniques for detecting impurities of such low concentration, in terms of sensitivity, may include electron paramagnetic resonance (EPR), as shown in FIG. 4, to be explained in more details below, and Secondary Ion Mass Spectrometry (SIMS).

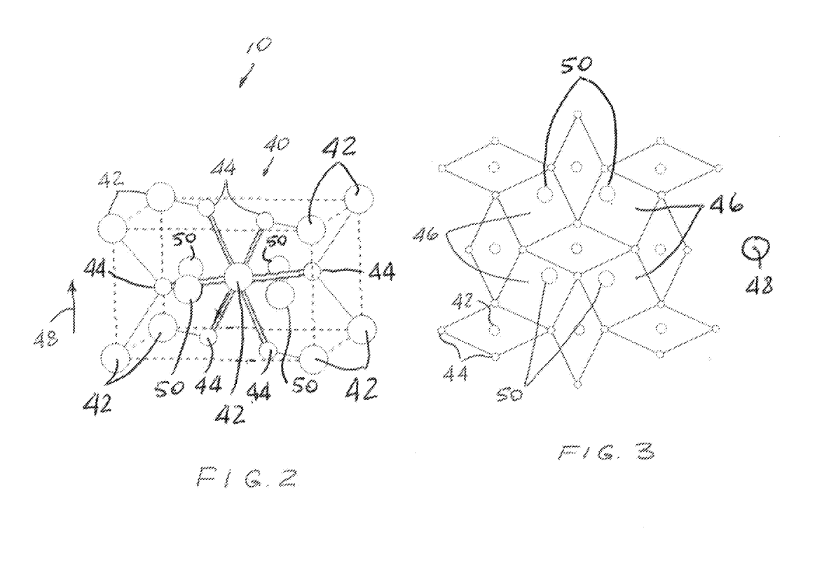

Now in reference to FIGS. 2-3, lithium ions 50 can be diffused into the TiO₂ rutile crystal 40, including titanium ions 42 and oxygen ions 44, through the “C”-axis channels 46 that run along the [001] crystallographic direction 48 of the crystal 40, as rutile has an extremely high diffusion constant along this crystallographic direction. At elevated temperature, the diffusion coefficient parallel to the [001] direction is about 10⁸ times larger than the diffusion coefficient perpendicular to the [001] direction, meaning that diffusion in this crystal is highly anisotropic.

A sum of the weight of sodium (Na) and potassium (K) impurities in the Li⁺-diffused TiO₂ rutile crystal may be below 0.10%. Weight percentages that fall below this threshold are typical of impurities that are present at the trace level; i.e., impurities that are unintentionally introduced during growth of the crystal.

High-temperature diffusion of lithium ions may be leveraged to intercalate or diffuse an isolated single Li⁺ ion into the structure of TiO₂. Li⁺ ions may be diffused into TiO₂ (rutile) by burying it in several compounds in an exemplary family of lithium-based powders, as shown in Table 3, and heating in a suitable environment for example such as a high-temperature furnace.

TABLE 3
Examples of other lithium-based compounds

| Name | Chemical formula |
|---|---|
| Lithium fluoride | LiF |
| Lithium bromide | LiBr |
| Lithium chloride | LiCl |
| Lithium Carbonate | Li₂CO₃ |
| Lithium Nitrate | LiNO₃ |

Several exemplary combinations of heating times, temperatures and pressures are shown in Table 4.

TABLE 4

| | Duration | Temperature | Atmospheric Pressure |
|---|---|---|---|
| NO | (hrs) | (° C.) | (atm) |
| 1 | 26 or | 450 ± 15 | 1 |
| | greater | | |
| 2 | 22 ± 3 | 450 ± 25 | 1 |
| 3 | 14 ± 4 | 450 ± 25 | 1 |
| 4 | 7 ± 2 | 475 ± 25 | 2 |
| 5 | 2.5 ± 1.5 | 500 or greater | 2 |

In one example, the crystal is heated to a nominal temperature of about 500° C. for a nominal duration of about 2.5 hours, which results in concentrations of lithium ions in the electrode material on the order of about 1×10¹⁵ cm⁻³. This example is presently preferred in a situation in which a less expensive battery cell 10 is desired.

In another example, the crystal is heated to a nominal temperature of about 450° C. for a duration equal to or greater than 26 hours, resulting in concentrations of lithium ions in the electrode material on the order of 1×10¹⁷ cm⁻³. This example is presently preferred when greater concentration, and thus improved performance of the battery cell 10 is desired. Other examples of temperatures and time durations, such as those displayed in Table 4, can be leveraged to produce an electrode with desired concentration based on cost and performance considerations.

Measurements showing successful intercalation of isolated Li⁺ ions into the TiO₂ (rutile) crystal structure are represented by a signature in an EPR spectrum, displayed in FIG. 4.

EPR is a powerful magnetic resonance technique that is used to detect and identify paramagnetic impurities within single crystalline semiconductors. The characteristics (i.e., number of individual peaks, the number of sets of peaks, peak separation, and relative intensity) of an EPR signature is defined by the number of unpaired electrons in the impurity's valence shell, the intrinsic nuclear spin of the nucleus being observed, and the natural abundance of each isotope of the nucleus being observed. The spectral signature in FIG. 4, containing a set of four equally intense peaks, marked in FIG. 4 with asterisks (*), demonstrates a presence of only the isolated single Li⁺ ion in TiO₂ rutile. This signature may be manifested directly from the presence of the Li⁺ ion inserted into the TiO₂ crystal lattice; the signal is not to be present if the Li⁺ ions are not present in the crystal. By way of an example only, the spectral signature in FIG. 4 was acquired after a TiO₂ crystal was heated in LiOH powder for about 18 hours. The peaks will have a higher amplitude with increased duration. The spectral signature displayed in FIG. 4 can be associated with the isolated single Li⁺ ion inserted into the crystalline lattice, at an interstitial lattice site, as a direct result of the diffusion process, proven by the fact that the signature in FIG. 4 is not present prior to performing the diffusion process. The high temperature diffusion method results in large concentrations of Li⁺ ion.

It has been further found that lithium intercalation via diffusion at temperatures in Table 4 results in lithium concentrations in a crystal on the order of between 5×10¹⁵-1×10¹⁷ cm⁻³. The lithium ions 50 occupy interstitial sites in the rutile lattice 40. A beneficial result of this Li-insertion process is the fact that only the isolated Li⁺ ion 50, and not a pair of Li⁺ ions 50, is present within the [001] or “C”-axis channels 46 after lithium is inserted into the lattice. Pairs of Li⁺ ions (i.e., two distinct Li⁺ ions that are directly adjacent to each other) within the c-axis channels 46 that run along the [001] direction inhibit diffusion of Li⁺ ions in the TiO₂ rutile lattice.

Using this material immediately mitigates thermal breakdown due to its low potential for thermal runaway due to lithium electroplating.

Now in reference to FIG. 5, a multi-cell battery pack 100 is provided, wherein individual battery cells 10, are connected in series with each other and may be further connected in a grid arrangement. Only two battery cells 10 are illustrated in FIG. 5, for the sake brevity.

In such multi-cell battery pack 100, transfer of concentrated heat from an overheated battery cell 10 to a neighboring battery cell 10 is a main reason for thermal runaway and cell-to-cell propagation of failure. While it is seen that a battery cell 10 that utilizes TiO₂ as the anode material is characterized by a greatly reduced thermal breakdown, propagation of thermal breakdown may be further mitigated by enclosing the battery cell 10 into a casing that conducts heat away from neighboring cells and diffuses hotspots. The battery cell 10 may be further encased in a heat-transfer-mitigating thermal foil 36 that conforms to the size and shape of the battery cell 10 while also reducing heat transfer to neighboring battery cells 10. This encasing may reduce or diffuse high temperatures due to hot spots in the individual battery cell 10, which could potentially result in thermal breakdown of a neighboring, properly functioning battery cell 10. Thus cell-to-cell propagation of thermal breakdown is mitigated.

A wall of the casing 20 of each battery cell 10 may include a vent opening 34.

The battery cell 10 and/or the multi-cell battery pack 100 may be characterized by an energy density over 1400 W*hr/l at 3V and may provide an improved thermal safety by drastically reducing thermal breakdown and reduced propagation of thermal cell failure, while using materials that are easily and inexpensively procurable.

In one example, the battery cell 10 comprises a casing 20, preferably manufactured from a metal, an anode 22 provided in the casing 20, the anode 22 containing a material including lithium ions intercalated into a single crystal of a titanium dioxide (TiO₂) on the order of between 5×10¹⁵-1×10¹⁷ cm⁻³. There is also a cathode or a positive electrode 24 provided in the casing 20. A separator 26 separates the anode 22 from the cathode 24. An electrolyte 30 is also disposed in the casing 20 wherein the anode 22, cathode 24 and the separator 26 are immersed into the electrolyte 30.

In another example, the battery cell 10 comprises a casing 20, preferably manufactured from a metal, an anode 22 provided in the casing 20, the anode 22 containing a material only including lithium ions intercalated into a single crystal of a titanium dioxide (TiO₂) on the order of between 5×10¹⁵-1×10¹⁷ cm⁻³. There is also a cathode or a positive electrode 24 provided in the casing 20. A separator 26 separates the anode 22 from the cathode 24. An electrolyte 30 is also disposed in the casing 20 wherein the anode 22, cathode 24 and the separator 26 are immersed into the electrolyte 30.

In one example, a capacity of TiO₂ may be in a range between 201 and 235 mA·hr/g.

In yet another example, the battery cell 10 comprises a casing 20, preferably manufactured from a metal, an anode or a negative electrode 22 provided in the casing 20, the negative electrode 22 containing a material including lithium ions intercalated into a single crystal of a titanium dioxide (TiO₂) on an order of about approximately 10¹⁶ cm⁻³. There is also a cathode (or a positive electrode during discharge) 24 provided in the casing 20 and being manufactured from a lithium cobalt oxide (LiCoO₂). A separator 26 separates the anode 22 from the cathode 24. An electrolyte 30 is also disposed in the casing 20 wherein the anode 22, cathode 24 and the separator 26 are immersed into the electrolyte 30 being manufactured from a lithium hexafluorophosphate (LiPF₆).

Either one of the described examples may include an optional pressure sensitive vent hole 34 formed through the wall of the casing 20 so as to release excess pressure within the casing 20 and thus operating as a safety feature.

The multi-cell battery pack 100 may further include the thermally-insulating foil 36 encasing the cell 10 so as to at least one of mitigate a thermal failure propagation, mitigate a heat conduction between cells 10, and promote heat conduction away from neighboring cells 10. This thermally insulating foil 36, which may be about 1 cm thick, operates to reduce the accumulation of high levels of heat in hot spots to neighboring cells 10, and hence further reduces the risk of the multi-cell batter pack 100 overheating.

In one example, the lithium-ion battery cell 10 may comprise a single crystalline Li⁺-intercalated titanium dioxide (TiO₂) crystal as the anode (negative during discharge) electrode material.

In another example, the lithium-ion battery cell 10 may comprise a single-crystalline Li⁺-intercalated titanium dioxide (TiO₂) crystal as the anode (negative electrode during discharge) material wherein Li⁺-ions are intercalated into TiO₂ (rutile) by diffusion at a temperature of about 450° C. for 6 or more hours.

In a further example, the lithium-ion battery cell 10 may be characterized by an improved thermal safety by reducing thermal breakdown caused by short circuiting in the anode material.

In another example, multi-cell battery pack 100 may be characterized by a reduced thermal runaway at the cell-level for reducing cell-to-cell propagation of failure, hence improving the safety and usefulness of the battery.

Thus, the chosen exemplary embodiments of the claimed invention has been described and illustrated for practical purposes as to enable any person skilled in the art to which it pertains to make and use the same. It will be understood that variations, modifications, equivalents and substitutions for components of the specifically described exemplary embodiments of the invention may be made by those skilled in the art without departing from the spirit and scope of the invention as set forth in the appended claims.

Furthermore, the Abstract is not intended to be limiting as to the scope of the claimed invention and is for the purpose of quickly determining the nature of the claimed invention.

We claim:

1. A method of manufacturing an electrode material to be used in a electrochemical battery, said method comprising the steps of:
(a) burying a titanium dioxide (TiO₂) crystal into a lithium hydroxide powder;
(b) heating, in a furnace, said titanium dioxide buried in said lithium hydroxide powder; and
(c) isolating a single lithium ion within each “C”-axis channel aligned along the crystallographic direction of said single TiO₂ crystal.

2. The method of claim 1, wherein the step (b) includes the step of heating said TiO₂ buried in said lithium hydroxide powder at a temperature between 425° C. and 475° C. for a duration of between 19 and 25 hours and at an atmospheric pressure of about 1 atmosphere (atm).

3. The method of claim 1, wherein the step (a) includes the step of burying only a single TiO₂ crystal in a rutile phase.

4. The method of claim 3, wherein step (b) includes the step of diffusing lithium ions into channels aligned along a crystallographic direction of said single TiO₂ crystal.

5. The method of claim 3, wherein the step (b) includes the step of producing Li⁺ concentrations in said electrode on the order of between 5×10¹⁵ cm⁻³ and 1×10¹⁷ cm⁻³.

6. The method of claim 1, wherein the step (b) comprises the step of heating said TiO₂ buried in said lithium hydroxide powder at an ambient pressure being greater than an atmospheric pressure.

7. The method of claim 1, further comprising the step of providing said TiO₂ in a rutile crystal form and intentionally doping said TiO₂ crystal, during growth thereof, with transition metal impurities being any one of or any combination of Iron (Fe), Chromium (Cr), Cobalt (Co), Niobium (Nb), Nickel (Ni), Aluminum (Al), Silver (Ag), Copper (Cu), Vanadium (V), Yttrium (Y), Zirconium (Zr), and Manganese (Mn).

8. The method of claim 8, wherein a concentration of said transition metal impurities is greater than 10¹³ cm⁻³.

9. A method of manufacturing an electrode material for use in an electrochemical battery, comprising the steps of:
(a) burying a titanium dioxide (TiO₂) of a rutile crystal type into a lithium hydroxide powder;
(b) heating said TiO₂ buried in said lithium hydroxide powder; and
(c) producing concentrations of lithium ions in said electrode material on an order of between 5×10¹⁵ cm⁻³ and 1×10¹⁷ cm⁻³.

10. The method of claim 9, further comprising the step of diffusing only a single lithium ion into channels aligned along the crystallographic direction of said single TiO₂ crystal.

11. A nonaqueous battery cell, comprising:
(a) a casing;
(b) an electrolyte disposed in said casing;
(c) a negative electrode provided in said casing, said negative electrode containing material including positively ionized lithium ions intercalated, with concentration on the order of 10¹⁶ cm⁻³, into a single crystal of titanium dioxide (TiO₂);
(d) a positive electrode provided in said casing; and
(e) a separator separating said negative electrode from said positive electrode.

12. The nonaqueous battery of claim 11, further comprising a vent opening in a wall of said casing.

13. The nonaqueous battery cell of claim 11, further comprising a member disposed on and surrounding an exterior surface of said casing, said member containing a material that reduces dissipation of heat concentration external to said casing during operation of said battery cell.

14. The nonaqueous battery cell of claim 11, wherein a capacity of said nonaqueous battery is in a range between 201 and 235 mA·hr/g.

15. The nonaqueous battery of claim 11, wherein said negative electrode material further comprises transition metal impurities being any one of Iron (Fe), Chromium (Cr), Cobalt (Co), Niobium (Nb), Nickel (Ni), Aluminum (Al), Silver (Ag), Copper (Cu), Vanadium (V), Yttrium (Y), Zirconium (Zr), and Manganese (Mn).

16. The nonaqueous battery cell of claim 15, wherein a concentration of said transition metal impurities is greater than 10¹³ cm⁻³.

17. The nonaqueous battery cell of claim 11, wherein said material further contains a single lithium ion isolated within each C-axis channel aligned along the crystallographic direction of said single TiO₂ crystal.

18. A nonaqueous battery cell, comprising:
(a) a casing;
(b) an electrolyte disposed in said casing and being manufactured from a lithium hexafluorophosphate (LiPF₆);
(c) a negative electrode provided in said casing, said negative electrode containing a material including lithium ions intercalated into a single crystal of a titanium dioxide (TiO₂) on an order of between 5×10¹⁵ cm⁻³ and 1×10¹⁷ cm⁻³;
(d) a positive electrode provided in said casing, said positive electrode containing a lithium cobalt oxide (LiCoO₂) material; and
(e) a separator separating said negative electrode from said positive electrode.

19. A nonaqueous battery comprising:
(a) two or more battery cells, each battery cell including:
i. a casing,
ii. a vent opening in a wall of said casing,
iii. an electrolyte disposed in said casing and containing a lithium hexafluorophosphate (LiPF₆)
iv. a negative electrode provided in said casing, said negative electrode containing a material having lithium ions intercalated into a single crystal of a titanium dioxide (TiO₂) on the order of between 5×10¹⁵ cm⁻³ and 1×10¹⁷ cm⁻³,
v. a positive electrode provided in said casing and containing a lithium cobalt oxide (LiCoO₂ material, and
vi. a separator separating said negative electrode from said positive electrode; and
(b) a thermally insulating foil disposed on an exterior surface of each casing so as to reduce a heat transfer between adjacent battery cells.
